(19) United States
(12) Patent Application Publication
(10) Pub. No.: US 2025/0392264 A1
(43) Pub. Date: Dec. 25, 2025

(54) RADIO FREQUENCY POWER AMPLIFIER

(71) Applicant: Nuvoton Technology Corporation Japan, Kyoto (JP)

(72) Inventors: Kaname MOTOYOSHI, Hyogo (JP); Masayuki MIYAJI, Nara (JP); Shinichi MARUYAMA, Kyoto (JP)

(21) Appl. No.: 19/313,333

(22) Filed: Aug. 28, 2025

Related U.S. Application Data
(63) Continuation of application No. PCT/JP2023/046936, filed on Dec. 27, 2023.
(60) Provisional application No. 63/492,943, filed on Mar. 29, 2023.

(51) Int. Cl. H03F 1/02; H03F 3/24

(52) U.S. Cl. CPC H03F 1/0261; H03F 3/245; H03F 2200/451

(57) ABSTRACT

A radio frequency power amplifier includes a power amplification transistor and a gate bias circuit. The gate bias circuit includes a VHb terminal connected to a high voltage power supply for bias, a VLb terminal connected to a low voltage power supply for bias, an enable terminal that receives an enable signal, an enable transistor and a voltage dividing resistor that are connected in series and connected between the VHb terminal and the VLb terminal, a driver that outputs a voltage to a control terminal of the enable transistor, and a gate bias output terminal that outputs, as a gate bias voltage, a divided voltage generated by the voltage dividing resistor. When an OFF signal is received as the enable signal, the driver causes the enable transistor to operate in a first operating area that is not a cutoff region.

### CROSS REFERENCE TO RELATED APPLICATIONS

This is a continuation application of PCT International Patent Application No. PCT/JP2023/046936 filed on Dec. 27, 2023, designating the United States of America, which is based on and claims priority of U.S. Provisional Patent Application No. 63/492,943 filed on Mar. 29, 2023. The entire disclosures of the above-identified applications, including the specifications, drawings and claims are incorporated herein by reference in their entirety.

### FIELD

The present disclosure relates to a radio frequency power amplifier used in an apparatus that transmits a radio frequency signal.

### BACKGROUND

In recent years, high power and high efficiency radio frequency power amplifiers are required in base stations for radio communications. A high electron mobility transistor (HEMT) using a group III nitride semiconductor such as gallium nitride (GaN) is capable of operating at high voltage and high current density, and is suitable for a high power and high efficiency radio frequency power amplifier. It is known, however, that in a GaN-HEMT, when the radio frequency power amplifier is switched from an ON state to an OFF state, a phenomenon called Idq drift in which a drain current decreases due to electron trapping in the crystal occurs. When Idq drift occurs, immediately after switching the radio frequency power amplifier from the OFF state to the ON state, the gain of the radio frequency power amplifier decreases to a lower value than an intended value due to the decrease in a drain current, and thus it takes time for the gain to recover to the desired value. In a base station for radio communications of a time division duplex (TDD) system, the rise time of the radio frequency power amplifier becomes a problem because the radio frequency power amplifier is caused to operate in the ON state during transmission and to operate in the OFF state during reception. Here, the rise time of the radio frequency power amplifier is the time from when a control signal that places the radio frequency power amplifier in an ON state is input to the radio frequency power amplifier to when the radio frequency power amplifier is in the ON state.

Conventionally, various techniques have been proposed to solve such problems as described above caused by Idq drift (see, for example, Patent Literatures (PTLs) 1 and 2). PTL 1 describes that, in regard to Idq drift, the gain and distortion characteristic stabilizing circuit recovers from the Idq drift state by temporarily making the gate bias voltage applied to the gate terminal of the transistor for current amplification shallow during the period when the radio frequency signal is not being supplied. In addition, in PTL 2, when the amplification device detects a decrease in the signal level of the input signal by the detection circuit, the gate bias circuit applies a second electric potential that is a value greater than or equal to the ground potential, and the drain bias circuit continues the state in which a drain bias voltage is not applied for a predetermined period of time, thereby recovering from the drift state.

### CITATION LIST

### Patent Literature

PTL 1: International Publication No. 2012/111451

PTL 2: Japanese Unexamined Patent Application Publication No. 2014-230133

### SUMMARY

### Technical Problem

With the technique according to PTL 1, however, a drain current flows even during the period in which a radio frequency signal is not supplied to the transistor for signal amplification, leading to a problem of an increase in standby current in the OFF state. In addition, the technique according to PTL 2 cannot be applied to the case where a drain bias voltage is constantly applied, as an amplification device for base stations for radio communications.

In view of the above, the present disclosure provides a radio frequency power amplifier capable of solving the above-described problem and reducing the rise time while keeping the standby current in the OFF state less than or equal to a certain value.

### Solution to Problem

In order to achieve the above, a radio frequency power amplifier according to one aspect of the present disclosure includes a power amplification transistor that includes a gate through which a radio frequency signal is input, a drain to output an amplified radio frequency signal, and a source connected to a ground potential; and a gate bias circuit that supplies a gate bias voltage to the gate of the power amplification transistor. In the radio frequency power amplifier, the gate bias circuit includes a first terminal connected to a high voltage power supply for bias, a second terminal connected to a low voltage power supply for bias, a third terminal that receives an enable signal, an enable transistor and a voltage dividing resistor that are connected in series and connected between the first terminal and the second terminal, a driver that outputs a voltage to a control terminal of the enable transistor, and a fourth terminal that outputs, as the gate bias voltage, a divided voltage generated by the voltage dividing resistor, the enable signal indicates a first logic when the radio frequency signal is not input to the gate of the power amplification transistor, and indicates a second logic when the radio frequency signal is input to the gate of the power amplification transistor, and the gate bias circuit: when the enable signal received by the third terminal indicates the first logic, outputs, through the fourth terminal, a voltage to turn off an operation of the power amplification transistor as the gate bias voltage, as a result of the driver (i) supplying the control terminal of the enable transistor with a voltage higher than a lowest voltage among voltages supplied to the driver and (ii) causing the enable transistor to operate in a first operating area that is not a cutoff region; and when the enable signal received by the third terminal indicates the second logic, outputs, through the fourth terminal, a voltage to turn on an operation of the power amplification transistor as the gate bias voltage, as a result of the driver causing the enable transistor to operate in a second operating area different from the first operating area.

Advantageous Effects With a radio frequency power amplifier according to the present disclosure, it is possible to reduce the rise time while keeping the standby current in the OFF state less than or equal to a certain value.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a diagram illustrating a radio frequency power amplifier according to Embodiment 1.

FIG. 2 is a diagram illustrating an example of the relationship between the current flowing through a gate bias circuit and the idle current of a power amplification transistor.

FIG. 3 is a diagram illustrating an example of the relationship between VLb and Vgef and the relationship between VLb and Ibof according to Embodiment 1.

FIG. 4 is a diagram illustrating an example of the circuit configuration of a driver according to Embodiment 1.

FIG. 5 is a diagram illustrating a radio frequency power amplifier according to Embodiment 2.

FIG. 6 is a time chart for describing the operation of a gate bias circuit according to Embodiment 2.

FIG. 7 is a diagram illustrating a radio frequency power amplifier according to Embodiment 3.

FIG. 8 is a diagram illustrating a radio frequency power amplifier according to Embodiment 4.

FIG. 9 is a diagram illustrating a radio frequency power amplifier according to Embodiment 5.

### DESCRIPTION OF EMBODIMENTS

Hereinafter, a radio frequency power amplifier according to embodiments will be described in detail with reference to the drawings. It should be noted that each of the exemplary embodiments described below shows one specific example of the present disclosure. The numerical values, shapes, materials, structural components, the arrangement and connection of the structural components, etc. shown in the following exemplary embodiments are mere examples, and therefore do not limit the scope of the present disclosure. In addition, the respective diagrams are not necessarily precise illustrations. In each of the diagrams, substantially the same structural components are assigned with the same reference signs, and there are instances where redundant descriptions will be omitted or simplified. In addition, in this Specification, “connection” means an electrical connection, and includes not only the case where two circuit elements are directly connected, but also the case where two circuit elements are indirectly connected with another circuit element inserted between the two circuit elements.

### Embodiment 1

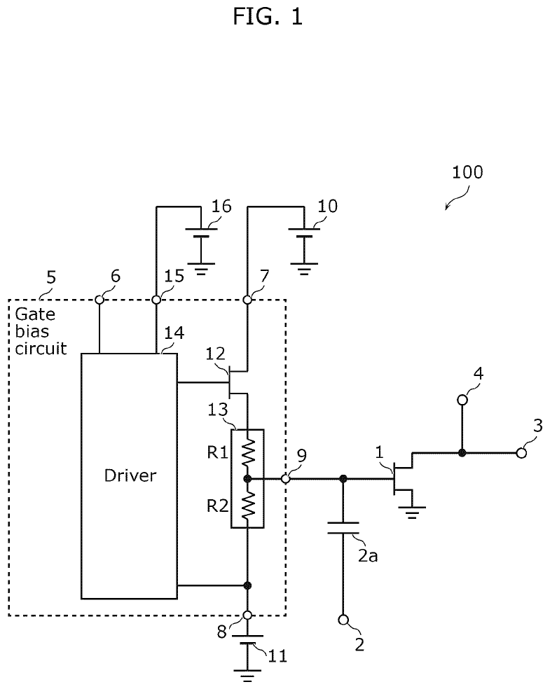

A radio frequency power amplifier according to Embodiment 1 will be described with reference to FIG. 1. FIG. 1 is a diagram illustrating radio frequency power amplifier 100 according to Embodiment 1.

Radio frequency power amplifier 100 includes, as main structural components, power amplification transistor 1 including a gate to which a radio frequency signal is input, a drain to output an amplified radio frequency signal, and a source connected to the ground potential, and gate bias circuit 5 that supplies a gate bias voltage to the gate of power amplification transistor 1. Gate bias circuit 5 includes VHb terminal 7 that is a first terminal connected to high voltage power supply for bias 10, VLb terminal 8 that is a second terminal connected to low voltage power supply for bias 11, enable terminal 6 that is a third terminal which receives an enable signal, enable transistor 12 and voltage dividing resistor 13 connected in series between VHb terminal 7 and VLb terminal 8, driver 14 that outputs a voltage to a control terminal of enable transistor 12, and gate bias output terminal 9 that is a fourth terminal which outputs a divided voltage generated by voltage dividing resistor 13 as a gate bias voltage. The enable signal indicates an OFF signal that is a first logic when no radio frequency signal is input to the gate of power amplification transistor 1, and indicates an ON signal that is a second logic when a radio frequency signal is input to the gate of power amplification transistor 1. When the enable signal received by enable terminal 6 indicates an OFF signal, gate bias circuit 5 outputs, through gate bias output terminal 9, a voltage to turn off the operation of power amplification transistor 1 as the gate bias voltage, as a result of driver 14 supplying the control terminal of enable transistor 12 with a voltage higher than the lowest voltage among voltages supplied to driver 14 and causing enable transistor 12 to operate in a first operating area that is not a cutoff region. When the enable signal received by enable terminal 6 indicates an ON signal, gate bias circuit 5 outputs, through gate bias output terminal 9, a voltage to turn on the operation of power amplification transistor 1 as the gate bias voltage, as a result of driver 14 causing enable transistor 12 to operate in a second operating area that is different from the first operating area. The following describes in detail each of the circuit elements.

Power amplification transistor 1 is constituted by a field effect transistor (FET) with a threshold voltage of Vtm.

A radio frequency signal that has been input via capacitor 2a from radio frequency signal input terminal 2 is input to the gate of power amplification transistor 1, and an amplified radio frequency signal is output from the drain to be output from radio frequency signal output terminal 3 to an external circuit (not illustrated in FIG. 1). A gate bias voltage is supplied to the gate of power amplification transistor 1 from gate bias circuit 5, and a drain voltage is supplied to the drain from power supply for output 4. The source of power amplification transistor 1 is connected to the ground potential.

Gate bias circuit 5 includes enable terminal 6, VHb terminal 7, VLb terminal 8, and gate bias output terminal 9. Enable terminal 6 receives an enable signal (ON/OFF signal). When a radio frequency signal is input to the gate of power amplification transistor 1, the enable signal indicates an ON voltage (e.g., 1.8 V) as an ON signal. On the other hand, when no radio frequency signal is input to the gate of power amplification transistor 1, the enable signal indicates an OFF voltage (e.g., 0 V) as an OFF signal. A voltage (VHb) is supplied to VHb terminal 7 from high voltage power supply for bias 10. A voltage (VLb) is supplied to VLb terminal 8 from low voltage power supply for bias 11. Gate bias output terminal 9 is connected to the gate of power amplification transistor 1, and outputs a different gate bias voltage according to the presence or absence of a radio frequency signal input to the gate of power amplification transistor 1.

Enable transistor 12 and voltage dividing resistor 13 connected in series are connected between VHb terminal 7 and VLb terminal 8. A divided voltage generated by voltage dividing resistor 13 is output as a gate bias voltage from gate bias output terminal 9. Enable transistor 12 is constituted by a field effect transistor with a threshold voltage of Vte. Voltage dividing resistor 13 is constituted by resistor R1 and resistor R2 connected in series, and the connecting point between R1 and resistor R2 is connected to gate bias output terminal 9.

Driver 14 applies a voltage generated from an enable signal (i.e., an ON signal or an OFF signal) that has been input to enable terminal 6, to the gate (control terminal) of enable transistor 12. When the enable signal indicates an ON signal (hereinafter, this case is simply referred to as “an ON state” or “an ON state of radio frequency power amplifier 100”), driver 14 applies control voltage Vgeo to the gate of enable transistor 12, and when the enable signal indicates an OFF signal (hereinafter, this case is simply referred to as “an OFF state” or “an OFF state of radio frequency power amplifier 100”), driver 14 applies control voltage Vgef to the gate of enable transistor 12. Driver 14 is connected to VLb terminal 8, and is supplied with voltage VLb from VLb terminal 8. In addition, gate bias circuit 5 includes driving voltage terminal 15, and a voltage from power supply for drive 16 is supplied to driver 14 via driving voltage terminal 15. It should be noted that driving voltage terminal 15 and power supply for drive 16 are not indispensable structural components. Since the control voltage of enable transistor 12 is generated from the voltage supplied to driver 14, it is optional that control voltage Vgef is higher than the lowest voltage (here, voltage VLb at VLb terminal 8) among the voltages supplied to driver 14. In other words, it is optional that Vgef>VLb.

Enable transistor 12 operates as a switch by the ON/OFF signal received at enable terminal 6. Conventionally, when enable transistor 12 is caused to perform an OFF operation by an OFF signal, enable transistor 12 is caused to operate in the cutoff region. In the cutoff region, enable transistor 12 is in the state of being caused to operate with the potential difference between the gate and source being lower than or equal to a threshold voltage. However, according to the present embodiment, enable transistor 12 in the OFF state is caused to operate in a first operating area that is not the cutoff region. The following describes the details.

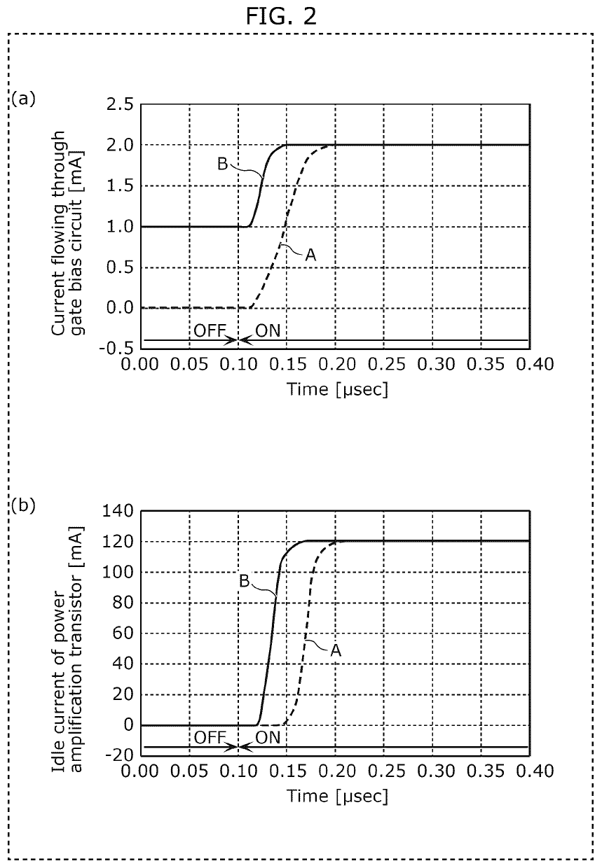

FIG. 2 illustrates a simulation result showing an example of the relationship between the current flowing through gate bias circuit 5 and the idle current of power amplification transistor 1. Here, the temporal changes of the current flowing through gate bias circuit 5 and the idle current of power amplification transistor 1 when the enable signal input to gate bias circuit 5 is switched from an OFF signal to an ON signal (i.e., when changed from an OFF state to an ON state) are indicated. In (a) of FIG. 2, the horizontal axis indicates time and the vertical axis indicates the current flowing through gate bias circuit 5. In (b) of FIG. 2, the horizontal axis indicates time and the vertical axis indicates the idle current of power amplification transistor 1. Here, the current flowing through gate bias circuit 5 corresponds to the current flowing between VHb terminal 7 and VLb terminal 8 according to Embodiment 1. In each of (a) and (b) of FIG. 2, dashed line A is the temporal change of the current when the current flowing through gate bias circuit 5 in an OFF state is 0, and solid line B is the temporal change of the current when the current flowing through gate bias circuit 5 in an OFF state is 1 mA.

In each of (a) and (b) of FIG. 2, at the point of 0.1 μsec, an ON signal is received as an enable signal which has previously been an OFF signal. As illustrated in (b) of FIG. 2, the time (i.e., timing) when the idle current of power amplification transistor 1 reaches a set value (120 mA in the case of (b) of FIG. 2) is earlier for solid line B than for dashed line A. In other words, the higher the current flowing through gate bias circuit 5 in an OFF state, the faster power amplification transistor 1 can be caused to perform an ON operation.

In view of the above, according to Embodiment 1, when an OFF signal is received at enable terminal 6, enable transistor 12 is caused to operate in the first operating area that is not the cutoff region. The first operating area is, for example, a saturation region. In order to cause enable transistor 12 to operate in the first operating area, the potential difference between the gate and source of enable transistor 12 needs to be higher than threshold voltage Vte of enable transistor 12.

Here, when an OFF signal is received at enable terminal 6, the current flowing between VHb terminal 7 and VLb terminal 8 (that is, the current flowing through gate bias circuit 5) is denoted by Ibof, and the resistance between VHb terminal 7 and VLb terminal 8 is denoted by Rt. In Embodiment 1, Rt is the sum of the resistance between the drain and source of enable transistor 12 and the resistance of voltage dividing resistor 13. However, since the resistance between the drain and source is negligibly smaller than the resistance of voltage dividing resistor 13, Rt is substantially equal to the resistance of voltage dividing resistor 13. At this time, control voltage Vgef applied to the gate (control terminal) of enable transistor 12 is sufficient if the following Expression (1) is satisfied.

$$Vgef > Vte + VLb + Ibof \times Rt \qquad ( 1 )$$

Accordingly, in the present embodiment, when an OFF signal is received at enable terminal 6, driver 14 generates control voltage Vgef that satisfies the above-described Expression (1) and applies control voltage Vgef generated to the gate of enable transistor 12, thereby outputting a gate bias voltage that causes power amplification transistor 1 to perform an OFF operation through gate bias output terminal 9.

On the other hand, when an ON signal is received at enable terminal 6, driver 14 causes enable transistor 12 to operate in the second operating area that is not the cutoff region. The second operating area is, for example, a linear region. Driver 14 generates control voltage Vgeo and applies control voltage Vgeo generated to the gate of enable transistor 12, thereby outputting a gate bias voltage that causes power amplification transistor 1 to perform an ON operation through gate bias output terminal 9. Control voltage Vgeo is, for example, 0 V.

Next, control voltage Vgef when even the gate bias voltage that causes power amplification transistor 1 to perform an ON operation and OFF operation is considered will be described. Here, Von−Vtm that is the voltage difference between gate bias voltage Von that causes power amplification transistor 1 to perform an ON operation and threshold voltage Vtm of power amplification transistor 1 is denoted by Y (Y>0). In other words, gate bias voltage Von that causes power amplification transistor 1 to perform an ON operation is Vtm+Y. Meanwhile, Vtm−Voff that is the voltage difference between threshold voltage Vtm of power amplification transistor 1 and gate bias voltage Voff that causes power amplification transistor 1 to perform an OFF operation is denoted by Z (Z>0). In other words, gate bias voltage Voff that causes power amplification transistor 1 to perform an OFF operation is Vtm−Z. When gate bias voltage Voff that causes power amplification transistor 1 to perform an OFF operation is lower than necessary, the recovery of Idq drift becomes slow, and thus Z is optionally set small. From the above, it can be seen that control voltage Vgef is sufficient if the relationship of the following Expression (2) is satisfied.

$$Vgef > Vte + [ ( Vtm - Z - VLb ) \times VHb + ( Y + Z ) \times VLb ] / ( Vtm + Y - VLb ) \qquad ( 2 )$$

When VHb is 0 V (ground potential), the above Expression (2) is represented as in the following Expression (3).

$$Vgef > Vte + [ ( Y + Z ) \times VLb ] / ( Vtm + Y - VLb ) \qquad ( 3 )$$

The ratio R2/R1 between resistor R1 and resistor R2 that constitute voltage dividing resistor 13 is represented by the following Expression (4).

$$R 2 / R 1 = [ ( Vtm + Y ) - VLb ] / [ VHb - ( Vtm + Y ) ] \qquad ( 4 )$$

At this time, current Ibof flowing through gate bias circuit 5 when the enable signal is an OFF signal can be calculated by the following Expression (5).

$$Ibof = [ ( Vtm - Z ) - VLb ] / R 2 \qquad ( 5 )$$

The above Expression (2) is, more specifically, derived by the following procedure.

It is assumed here that the current between VHb terminal 7 and VLb terminal 8 does not flow in the direction toward gate bias output terminal 9.

When the source voltage of enable transistor 12 is Vs, based on the voltage relationship (i.e., saturation region operation) at gate bias output terminal 9 in the OFF state, Vtm−Z is obtained using Vs[=(Vgef−Vte)], VLb, and the resistance of the voltage dividing resistor, and thus the following expression is derived.

$$Vtm - Z = ( Vgef - Vte - VLb ) \times R 2 / ( R 1 + R 2 ) + VLb \qquad ( 2 - 1 )$$

In addition, based on the voltage relationship at gate bias output terminal 9 in the ON state, Vtm+Y is obtained using Vs[=(VHb)], VLb, and the resistance of the voltage dividing resistor, and thus the following expression is derived.

$$Vtm + Y = ( VHb - VLb ) \times R 2 / ( R 1 + R 2 ) + VLb \qquad ( 2 - 2 )$$

From the above Expression (2-2), the following expression is derived.

$$R 2 / ( R 1 + R 2 ) = ( Vtm + Y - VLb ) / ( VHb - VLb ) \qquad ( 2 - 3 )$$

Here, when substituting the above Expression (2-3) into the above Expression (2-1), the following expression is obtained.

$$Vtm - Z = ( Vgef - Vte - VLb ) \times ( Vtm + Y - VLb ) / ( VHb - VLb ) + VLb$$

Furthermore, when the above expression is rearranged with Vaef, the following Expression (2-4) is derived.

$$Vgef = ( Vtm - Z - VLb ) \times ( VHb - VLb ) / ( Vtm + Y - VLb ) + ( Vte + VLb ) = Vte + [ ( Vtm - Z - VLb ) \times ( VHb - VLb ) + VLb \times ( Vtm + Y - VLb ) ] \text{} / ( Vtm + Y - VLb ) = Vte + [ ( Vtm - Z - VLb ) \times VHb + ( Y + Z ) \times VLb ] / [ ( Vtm + Y ) - VLb ] \qquad ( 2 - 4 )$$

Here, in the above Expression (2-4), it is the boundary between the cutoff region and the saturation region when the equality is satisfied, and thus the following Expression (2) is derived if the equal sign “=” is replaced with the inequality sign “>”.

$$Vgef > Vte + [ ( Vtm - Z - VLb ) \times VHb + ( Y + Z ) \times VLb ] / [ ( Vtm + Y ) - VLb ] \qquad ( 2 )$$

The above Expression (4) is, more specifically, derived by the following procedure.

When the above Expression (2-2) is rearranged with R2/R1, the ratio of resistances of voltage dividing resistors [(R1+R2)/R2] is represented as in the following expression.

$$( R 1 + R 2 ) / R 2 = ( VHb - VLb ) / ( Vtm + Y - VLb )$$

When this is rearranged, the following expression is derived.

$$R 1 / R 2 + 1 = ( VHb - VLb ) / ( Vtm + Y - VLb )$$

When this is further rearranged, the following expression is derived.

$$R 1 / R 2 = ( VHb - VLb ) / ( Vtm + Y - VLb ) - 1 = [ ( VHb - ( V t m + Y ) ] / ( Vtm + Y - VLb )$$

Accordingly, the ratio between resistance R1 and resistance R2 is represented by Expression (4) below.

$$R 2 / R 1 = [ ( Vtm + Y ) - VLb ] / [ VHb - ( Vtm + Y ) ] \qquad ( 4 )$$

From the above, it can be seen that R2/R1 is determined by gate bias voltage Von of power amplification transistor 1 in the ON state; that is, (Vtm+Y).

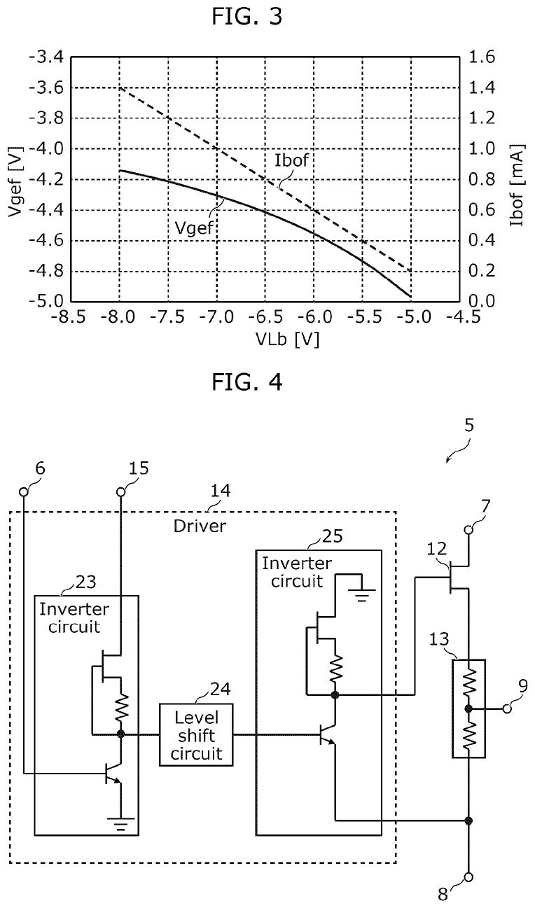

From the above Expressions (2) to (5), the relationship between VLb and Vgef and the relationship between VLb and Ibof are represented as in FIG. 3, as an example. FIG. 3 is a diagram illustrating an example of the relationship between VLb and Vgef and the relationship between VLb and Ibof according to Embodiment 1. In FIG. 3, threshold voltage Vtm of power amplification transistor 1 is −2.5 V, threshold voltage Vte of enable transistor 12 is −0.8 V, VHb is 0 V, gate bias voltage Von that causes power amplification transistor 1 to perform an ON operation is −2 V (Y=0.5), gate bias voltage Voff that causes power amplification transistor 1 to perform an OFF operation is −4.5 V (Z=2), the resistance of resistor R2 of voltage dividing resistor 13 is 2.5 kΩ. The horizontal axis indicates VLb, the left vertical axis indicates control voltage Vgef, and the right vertical axis indicates Ibof. The solid line indicates the lower limit of Vgef (i.e., the value corresponding to the right-hand side in the above Expression (3)), and the dashed line indicates Ibof. For example, when VLb is −7 V, it is sufficient if Vgef is set to be higher than −4.3 V, and at this time a current of 1 mA flows through gate bias circuit 5. The resistance of resistor R1 is 1 kΩ from the above Expression (4).

With radio frequency power amplifier 100 according to Embodiment 1, when no radio frequency signal is input to the gate of power amplification transistor 1, an OFF signal is received at enable terminal 6 as an enable signal, and driver 14 causes enable transistor 12 to operate in the first operating area that is not the cutoff region, and a constant current Ibof is applied to gate bias circuit 5, thereby making it possible to reduce the rise time of radio frequency power amplifier 100. In addition, since power amplification transistor 1 is completely in an OFF state when no radio frequency signal is input to the gate of power amplification transistor 1, the drain current of power amplification transistor 1 does not flow, and only the current flowing through gate bias circuit 5 can be the standby current of radio frequency power amplifier 100.

It should be noted that, enabling transistor 12 has been described as a field-effect transistor in Embodiment 1, but is not limited to this. Enabling transistor 12 may be constituted by a bipolar transistor. In the case of a bipolar transistor, the first operating area is an active region and the second operating area is a saturation region.

It should be noted that, although power amplification transistor 1 has been described as a field effect transistor in Embodiment 1, power amplification transistor 1 may also be a normally-on field-effect transistor. In addition, a group III nitride semiconductor may be used as the semiconductor that constitutes power amplification transistor 1. GaN may also be used as the group III nitride semiconductor.

GaAs and GaN may also be used as semiconductors that constitute gate bias circuit 5.

In addition, driver 14 can be constituted by an inverter circuit, a level shift circuit, etc. The level shift circuit is a circuit that shifts the voltage by a certain value. FIG. 4 is a diagram illustrating an example of the circuit configuration of driver 14 according to Embodiment 1. Driver 14 is constituted by inverter circuits 23 and 25 and level shift circuit 24. Inverter circuit 23 is connected to enable terminal 6 and driving voltage terminal 15. The output of inverter circuit 23 is input to level shift circuit 24. Level shift circuit 24 can be configured by connecting a plurality of diodes in series. The output of level shift circuit 24 is input to inverter circuit 25. Inverter circuit 25 is also connected to VLb terminal 8, and the output of inverter circuit 25 is applied to the gate of enable transistor 12.

As described above, radio frequency power amplifier 100 according to the present embodiment includes power amplification transistor 1 that includes a gate through which a radio frequency signal is input, a drain to output an amplified radio frequency signal, and a source connected to a ground potential; and gate bias circuit 5 that supplies a gate bias voltage to the gate of power amplification transistor 1. In radio frequency power amplifier 100, gate bias circuit 5 includes VHb terminal 7 connected to high voltage power supply for bias 10, VLb terminal 8 connected to low voltage power supply for bias 11, enable terminal 6 that receives an enable signal, enable transistor 12 and voltage dividing resistor 13 that are connected in series and connected between VHb terminal 7 and VLb terminal 8, driver 14 that outputs a voltage to a control terminal of enable transistor 12, and gate bias output terminal 9 that outputs, as the gate bias voltage, a divided voltage generated by voltage dividing resistor 13, the enable signal indicates an OFF signal when the radio frequency signal is not input to the gate of power amplification transistor 1, and indicates an ON signal when the radio frequency signal is input to the gate of power amplification transistor 1, and gate bias circuit 5: when the enable signal received by enable terminal 6 indicates the OFF signal, outputs, through gate bias output terminal 9, a voltage to turn off an operation of power amplification transistor 1 as the gate bias voltage, as a result of driver 14 (i) supplying the control terminal of enable transistor 12 with a voltage higher than a lowest voltage among voltages supplied to driver 14 (voltage VLb at VLb terminal 8 in the embodiment) and (ii) causing enable transistor 12 to operate in a first operating area that is not a cutoff region; and when the enable signal received by enable terminal 6 indicates the ON signal, outputs, through gate bias output terminal 9, a voltage to turn on an operation of power amplification transistor 1 as the gate bias voltage, as a result of driver 14 causing enable transistor 12 to operate in a second operating area different from the first operating area.

In this manner, when radio frequency power amplifier 100 is in an OFF state, enable transistor 12 operates in the first operating area that is not the cutoff region, and thus a constant current Ibof flows through gate bias circuit 5. As a result, the rise time of radio frequency power amplifier 100 is reduced. In addition, when radio frequency power amplifier 100 is completely in an OFF state, power amplification transistor 1 performs completely an OFF operation, and thus a current does not flow through power amplification transistor 1. As a result, the standby current of radio frequency power amplifier 100 is only the current flowing through gate bias circuit 5. It is thus possible to implement radio frequency power amplifier 100 that can reduce the rise time while keeping the standby current in the off state less than or equal to a certain value.

Here, enable transistor 12 is a field effect transistor, and the first operating area is a saturation region, or enable transistor 12 is a bipolar transistor, and the first operating area is an active region. In this manner, when radio frequency power amplifier 100 is in an OFF state, enable transistor 12 operates in the saturation region if enable transistor 12 is an FET, and enable transistor 12 operates in the active region if enable transistor 12 is a bipolar transistor. As a result, it is reliably ensured that constant current Ibof flows through gate bias circuit 5.

In addition, a voltage that is denoted by Vgef, and is applied by driver 14 to the control terminal of enable transistor 12 to cause enable transistor 12 to operate in the first operating area satisfies Vgef>Vte+[(Vtm−Z−VLb)×VHb+(Y+Z)×VLb]/(Vtm+Y−VLb), where Vtm denotes a threshold voltage of power amplification transistor 1, Vte denotes a threshold voltage of enable transistor 12, VHb denotes a voltage supplied to VHb terminal 7, VLb denotes a voltage supplied to VLb terminal 8, Von denotes a gate bias voltage output by gate bias circuit 5 to turn on an operation of power amplification transistor 1, Y denotes Von-Vtm that is a voltage difference between Von and Vtm, Voff denotes a gate bias voltage output by gate bias circuit 5 to turn off an operation of power amplification transistor 1, and Z denotes Vtm−Voff that is a voltage difference between Vtm and Voff, Y is greater than zero, and Z is greater than zero. In this manner, when radio frequency power amplifier 100 is in an OFF state, it is possible to cause power amplification transistor 1 to reliably perform an OFF operation, and cause enable transistor 12 to operate in the first operating area to avoid the recovery of Idq drift from becoming slow.

### Embodiment 2

Next, a radio frequency power amplifier according to Embodiment 2 will be described.

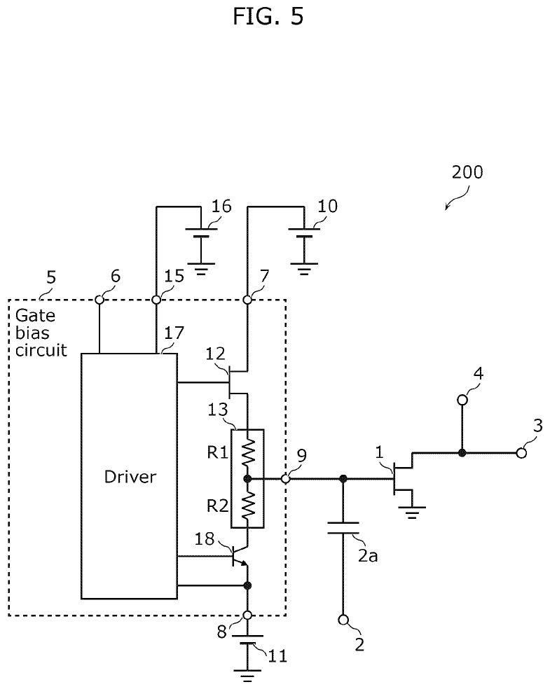

FIG. 5 is a diagram illustrating radio frequency power amplifier 200 according to Embodiment 2. Hereafter, descriptions will be provided with a focus on the points different from radio frequency power amplifier 100. Radio frequency power amplifier 200 includes variable resistor 18 connected between voltage dividing resistor 13 and VLb terminal 8. According to the present embodiment, variable resistor 18 is constituted by a transistor. As a transistor, a bipolar transistor or a field effect transistor of a normally off type may be used. The base (control terminal) of variable resistor (here, transistor) 18 is connected to driver 17, and a control voltage generated from an enable signal (i.e., an ON signal or an OFF signal) is applied to the base. In addition, as to control on enable transistor 12, in the same manner as in Embodiment 1, driver 17 applies a voltage generated from an enable signal (i.e., an ON signal or an OFF signal) to the gate (control terminal) of enable transistor 12.

When a radio frequency signal is not input to the gate of power amplification transistor 1, the standby current of radio frequency power amplifier 200 is only the current flowing through gate bias circuit 5, in the same manner as Embodiment 1. For base station systems for radio communications including a radio frequency power amplifier, there is a demand for keeping the standby current of the radio frequency power amplifier less than or equal to a certain value. In order to reduce the standby current, from the above Expression (5), increasing VLb or the resistance of resistor R2 can be considered. However, when low voltage power supply for bias 11 is present in the base station systems for radio communications and VLb is supplied, VLb cannot be changed freely. In addition, when large resistor R2 is formed with a semiconductor, the area becomes large. When forming a resistor with a semiconductor, it is optional that the resistance of the resistor is less than or equal to 10 kΩ.

In view of the above, in radio frequency power amplifier 200 according to Embodiment 2, the standby current is reduced using variable resistor 18. More specifically, driver 17 controls the resistance value of variable resistor 18 such that the resistance value of variable resistor 18 is Rvf when an OFF signal is received at enable terminal 6, and the resistance value of variable resistor 18 is Rvo when an ON signal is received at enable terminal 6. At this time, Rvf>Rvo is satisfied. In the case where variable resistor 18 is constituted by a transistor, when an OFF signal is received at enable terminal 6, driver 17 applies a voltage that causes the transistor constituting variable resistor 18 to perform an OFF operation to the base of the transistor. With this, since the transistor performs an OFF operation, the resistance (Rvf) between the collector and emitter of the transistor becomes a high resistance. On the other hand, when an ON signal is received at enable terminal 6, driver 17 applies a voltage that causes the transistor constituting variable resistor 18 to perform an ON operation to the base of the transistor. With this, since the transistor performs an ON operation, the resistance (Rvo) between the collector and emitter of the transistor becomes a low resistance. Here, since Rvo is much smaller than the resistance of voltage dividing resistor 13, when an ON signal is received at enable pin 6, the operation of radio frequency power amplifier 200 is substantially the same as the operation of radio frequency power amplifier 100 of Embodiment 1. On the other hand, when an OFF signal is received at enable terminal 6, the denominator in the above Expression (5) is changed from R2 to R2+Rvf, and thus it is possible to reduce current Ibof flowing through gate bias circuit 5.

For the set value of Ibof, Rvf is represented by the following Expression (6).

$$Rvf = Rvo + 1 / Ibof \times [ ( Vtm - Z - VLb ) \times VHb - ( Vgef - Vte ) \times ( Vtm + Y - VLb ) + ( Y + Z ) \times VLb ] / [ VHb - ( Vtm + Y ) ] \qquad ( 6 )$$

When VHb is 0 V (ground potential) and Rvo is 0Ω, the above Expression (6) is represented by the following Expression (7).

$$Rvf = 1 / Ibof \times [ ( Vgef - Vte ) \times ( Vtm + Y - VLb ) - ( Y + Z ) \times VLb ] / ( Vtm + Y ) ] \qquad ( 7 )$$

For example, when threshold voltage Vtm of power amplification transistor 1 is −2.5 V, threshold voltage Vte of enable transistor 12 is −0.8 V, VHb is 0 6l V, VLb is −7 V, gate bias voltage Von that causes power amplification transistor 1 to perform an ON operation is −2 V (Y=0.5), gate bias voltage Voff that causes power amplification transistor 1 to perform an OFF operation is −4.5 V (Z=2), control voltage Vgef of enable transistor 12 is −5V, Rvo is 0 Ω, and Ibof is 0.3 mA, it is sufficient to set Rvf to 5.8 6l kΩ.

It should be noted that, more specifically, the above Expression (6) is derived by the following procedure.

As in the derivation of the above Expression (2), it is assumed here that the current between VHb terminal 7 and VLb terminal 8 does not flow in the direction toward gate bias output terminal 9 It is also assumed here that the current flowing in the ON state between VHb terminal 7 and VLb terminal 8 (=i.e., the current flowing through gate bias circuit 5) is Ibon.

First, focusing on the current flowing between gate bias output terminal 9 and VLb terminal 8, the following Expression (6-1) is satisfied in the OFF state.

$$Ibof = [ ( Vtm - Z ) - VLb ] / ( R 2 + Rvf ) \qquad ( 6 - 1 )$$

On the other hand, the following Expression (6-2) is satisfied in the ON state.

$$Ibon = [ ( Vtm + Y ) - VLb ] / ( R 2 + Rvo ) \qquad ( 6 - 2 )$$

From Expression (6-2), the following Expressions (6-3) are derived.

$$R 2 + Rvo = [ ( Vtm + Y ) - VLb ] / Ibon R 2 = [ ( Vtm + Y ) - VLb ] / Ibon - Rvo \qquad ( 6 - 3 )$$

When the above Expression (6-1) is rearranged with Rvf, the following expression is satisfied.

$$R 2 + Rvf = [ ( Vtm - Z ) - VLb ] / Ibof$$

Furthermore, the following expression is satisfied.

$$Rvf = [ ( Vtm - Z ) - VLb ] / Ibof - R 2 \qquad ( 6 - 4 )$$

Here, when substituting the above Expression (6-3) into the above Expression (6-4), the following Expression (6-5) is derived.

$$Rvf = [ ( Vtm - Z ) - VLb ] / Ibof - [ ( Vtm + Y ) - VLb ] / Ibon + Rvo \qquad ( 6 - 5 )$$

Next, focusing on the current flowing between the source of enable transistor 12 and VLb terminal 8 (i.e., focusing on the fact that a current does not flow in the direction toward gate bias output terminal 9), the following expression is satisfied in the OFF state.

$$Ibof = [ ( Vgef - Vte ) - VLb ] / ( R 1 + R 2 + Rvf ) \qquad ( 6 - 6 )$$

On the other hand, the following Expression (6-7) is satisfied in the ON state.

$$Ibon = [ ( V H b - V L b ) ] / ( R 1 + R 2 + Rvo ) \qquad ( 6 - 7 )$$

Here, from the above Expression (6-6), the following Expression (6-8) is derived.

$$R 1 + R 2 = [ ( Vgef - Vte ) - VLb ] / Ibof - Rvf \qquad ( 6 - 8 )$$

When substituting this Expression (6-8) into the above Expression (6-7), the following Expression (6-9) is derived.

$$Ibon = [ ( V H b - V L b ) ] / [ [ ( Vgef - Vte ) - VLb ] / Ibof - Rvf + Rvo ] \qquad ( 6 - 9 )$$

When substituting the above Expression (6-9) into the above Expression (6-5) to remove Ibon from the expression, and rearranging the expression with Rvf, the following Expression (6) is derived.

$$Rvf = Rvo + 1 / Ibof \times [ ( Vtm - Z - VLb ) \times VHb - ( Vgef - Vte ) \times ( Vtm + Y - VLb ) + ( Y + Z ) \times VLb ] / [ VHb - ( Vtm + Y ) ] \qquad ( 6 )$$

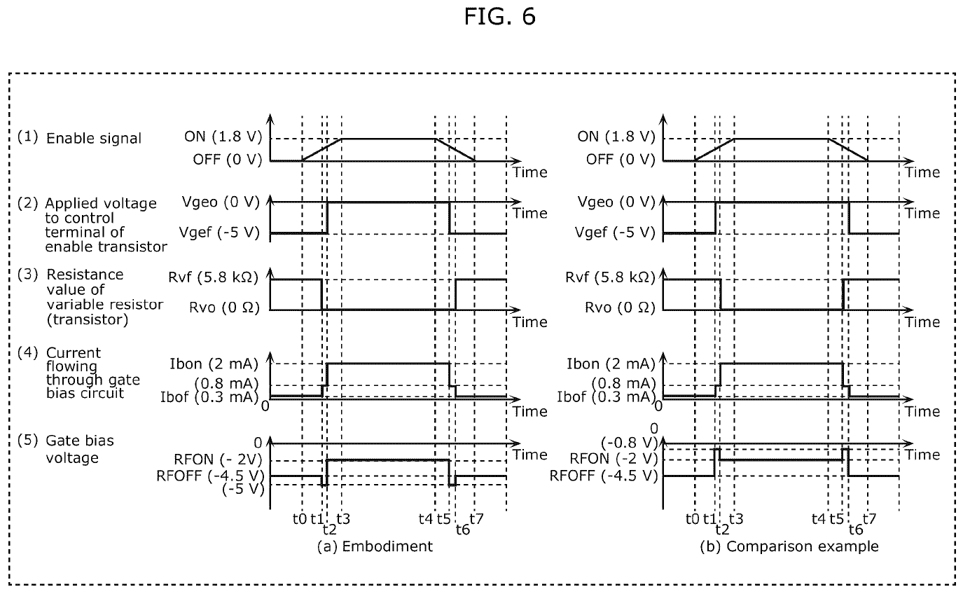

The following describes the switching operation by driver 17 for enable transistor 12 and variable resistor 18 when an ON signal is received at enable terminal 6 (i.e., the switching operation from the operation when an OFF signal is received at enable terminal 6 to the operation when an ON signal is received at enable terminal 6). FIG. 6 is a time chart for describing the operation of gate bias circuit 5 according to Embodiment 2. In FIG. 6, (a) is a time chart of Embodiment 2, and (b) is a time chart of a comparison example. In FIG. 6, the horizontal axis indicates time, the vertical axis indicates (1) the waveform of the enable signal, (2) the waveform of the applied voltage to the control terminal of enable transistor 12, (3) the waveform of the resistance value of variable resistor 18, (4) the waveform of the current flowing through gate bias circuit 5, and (5) the waveform of the gate bias voltage.

First, the comparison example indicated by (b) of FIG. 6 will be described. The comparison example shows an example in which the switching operation of enable transistor 12 is carried out prior to the switching operation of variable resistor 18 when an ON signal is received at enable terminal 6. It is assumed that the enable signal changes from 0 V (OFF signal) to 1.8 V (ON signal) from t0 to t3. It is assumed that the control voltage to enable transistor 12 changes from Vgef to Vgeo at t1, and the resistance value of variable resistor 18 changes from Rvf to Rvo at t2 (>t1). At this time, the gate bias voltage becomes higher (−0.8 V in (b) of FIG. 6) at t1 than a set gate bias voltage (−2 V in (b) of FIG. 6) that causes power amplification transistor 1 to perform an ON operation, and then becomes the set gate bias voltage at t2. As a result, during the period from t1 to t2, the voltage higher than the set gate bias voltage is applied to the gate of power amplification transistor 1, and thus there is a possibility that the idle current of power amplification transistor 1 becomes excessively larger than the set value, leading to possible destruction of power amplification transistor 1.

On the other hand, in Embodiment 2 indicated by (a) of FIG. 6, an example is shown in which the switching operation of variable resistor 18 is carried out prior to the switching operation of enable transistor 12 when an ON signal is received at enable terminal 6. It is assumed that the enable signal changes from 0 V (OFF signal) to 1.8 V (ON signal) from t0 to t3. It is assumed that the resistance value of variable resistor 18 changes from Rvf to Rvo at t1, and the control voltage to enable transistor 12 changes from Vgef to Vgeo at t2 (>t1). At this time, the gate bias voltage becomes lower (−5 V in (a) of FIG. 6) at t1 than the set gate bias voltage (−2 V in (a) of FIG. 6) that causes power amplification transistor 1 to perform an ON operation, and then becomes the set gate bias voltage at t2. During the period from t1 to t2, a voltage higher than the set gate bias voltage is not applied to the gate of power amplification transistor 1, and thus there is little possibility that power amplification transistor 1 is destroyed due to the switching operation.

The settings to achieve such timing indicated in (a) of FIG. 6 are as follows. The voltage that is applied to the control terminal of variable resistor 18 to switch the resistance value of variable resistor 18 from Rvf to Rvo in response to a change in the enable signal from an OFF signal to an ON signal is set to be lower than the voltage at which the control voltage to enable transistor 12 switches from Vgef to Vgeo, thereby making it possible to switch variable resistor 18 prior to enabling transistor 12.

Radio frequency power amplifier 200 according to Embodiment 2 enables the standby current of radio frequency power amplifier 200 to be kept less than or equal to a set value. In addition, by constituting variable resistor 18 with a transistor, it is possible to readily change the resistance value of variable resistor 18 by the voltage applied to the control terminal (base) of variable resistor 18. When an ON signal is received at enable terminal 6, variable resistor 18 performs the switching operation prior to enable transistor 12, thereby enabling to inhibit power amplification transistor 1 from being destroyed.

As described above, radio frequency power amplifier 200 according to the present embodiment further includes, in addition to the structural components of radio frequency power amplifier 100 according to Embodiment 1, variable resistor 18 connected between voltage dividing resistor 13 and VLb terminal 8. In radio frequency power amplifier 200, driver 17 controls a resistance value of variable resistor 18 to satisfy Rvo<Rvf, where Rvf denotes the resistance value of variable resistor 18 when the enable signal indicating the OFF signal is received by enable terminal 6, and Rvo denotes the resistance value of variable resistor 18 when the enable signal indicating the ON signal is received by enable terminal 6.

In this manner, variable resistor 18 is inserted in series with enable transistor 12 and voltage dividing resistor 13, and the resistance value of variable resistor 18 when radio frequency power amplifier 200 is in an OFF state is controlled to be larger than the resistance value of variable resistor 18 when radio frequency power amplifier 200 is in an ON state. As a result, the standby current of radio frequency power amplifier 200 can be kept less than or equal to the set value.

In addition, variable resistor 18 is a transistor, and driver 17 switches the resistance value of variable resistor 18 to Rvo or to Rvf, by applying a voltage generated using the enable signal received by enable terminal 6 to a control terminal of the transistor. In this manner, the resistance value of variable resistor 18 is readily switched under control by driver 17.

In addition, Rvf=Rvo+1/Ibof×[(Vtm−Z−VLb)×VHb−(Vgef−Vte)×(Vtm+Y−VLb)+(Y+Z)×VLb]/[VHb−(Vtm+Y)] is satisfied, where Ibof denotes a current flowing between VHb terminal 7 and VLb terminal 8 when the enable signal indicating the OFF signal is received by enable terminal 6, Vgef denotes a voltage that is applied by the driver to the control terminal of enable transistor 12 to cause enable transistor 12 to operate in the first operating area, Vtm denotes a threshold voltage of the power amplification transistor, Vte denotes a threshold voltage of enable transistor 12, VHb denotes a voltage supplied to VHb terminal 7, VLb denotes a voltage supplied to VLb terminal 8, Y denotes Von-Vtm that is a voltage difference between Von and Vtm, Von denotes a gate bias voltage output by the gate bias circuit to turn on an operation of the power amplification transistor, Z denotes Vtm−Voff that is a voltage difference between Vtm and Voff, Voff denotes a gate bias voltage output by the gate bias circuit to turn off an operation of the power amplification transistor, Y is greater than zero, and Z is greater than zero. In this manner, current Ibof flowing through gate bias circuit 5 when radio frequency power amplifier 200 is in an OFF state is suppressed to the set value.

In addition, when the enable signal changes from a signal indicating the OFF signal to a signal indicating the ON signal, driver 17 causes enable transistor 12 to switch from operating in the first operating area to operating in the second operating area after switching the resistance value of variable resistor 18 from Rvf to Rvo. In this manner, it is possible to avoid a voltage higher than the set gate bias voltage from being applied to the gate of power amplification transistor 1. As a result, it is possible to inhibit power amplification transistor 1 from being destroyed.

### Embodiment 3

Next, a radio frequency power amplifier according to Embodiment 3 will be described.

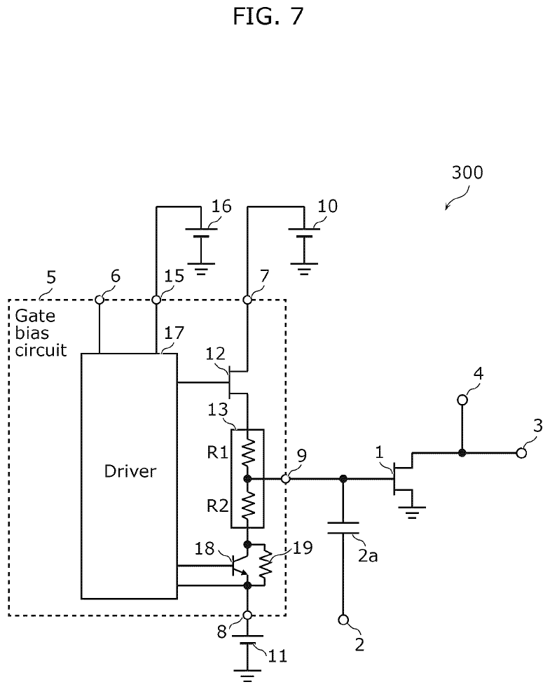

FIG. 7 is a diagram illustrating radio frequency power amplifier 300 according to Embodiment 3. Radio frequency power amplifier 300 has a configuration in which fixed resistor 19 is added in parallel with variable resistor (transistor) 18 of radio frequency power amplifier 200 according to Embodiment 2 between a collector and an emitter of variable resistor 18. Hereafter, descriptions will be provided with a focus on the points different from radio frequency power amplifier 200 according to Embodiment 2.

When an OFF signal is received at enable terminal 6, it is sufficient if resistance value Rvf of variable resistor 18 is a value that satisfies the relationship of the above Expression (6) including Ibof. However, when variable resistor 18 is constituted by a transistor, there are instances where designing variable resistor 18 to have resistance value Rvf with high accuracy using only transistors is difficult. In view of the above, fixed resistor 19 is added in parallel with variable resistor (transistor) 18 between the collector and the emitter of variable resistor 18, thereby making it easy to design the variable resistor. When the resistance value of fixed resistor 19 is denoted by Rfix, it is sufficient if the left side of the above Expression (6) is replaced from Rvf to the parallel resistance of Rvf and Rfix. The parallel resistance of Rvf and Rfix is represented by Rvf×Rfix/(Rvf+Rfix).

On the other hand, when an ON signal is received at enable terminal 6, the parallel resistance of resistance value Rvo of variable resistor 18 and Rfix is approximately Rvo if Rvo is negligibly small compared to Rfix. At this time, the operation of radio frequency power amplifier 300 is the same as the operation of radio frequency power amplifier 200 according to Embodiment 2.

As described above, radio frequency power amplifier 300 according to the present embodiment further includes, in addition to the structural components of radio frequency power amplifier 200 according to Embodiment 2, fixed resistor 19 connected in parallel with variable resistor 18.

With radio frequency power amplifier 300 according to Embodiment 3, by adding fixed resistor 19 in parallel with variable resistor (transistor) 18 between the collector and emitter of variable resistor 18, it is possible to design an intended resistance value with high accuracy to inhibit current Ibof flowing through gate bias circuit 5.

### Embodiment 4

Next, a radio frequency power amplifier according to Embodiment 4 will be described.

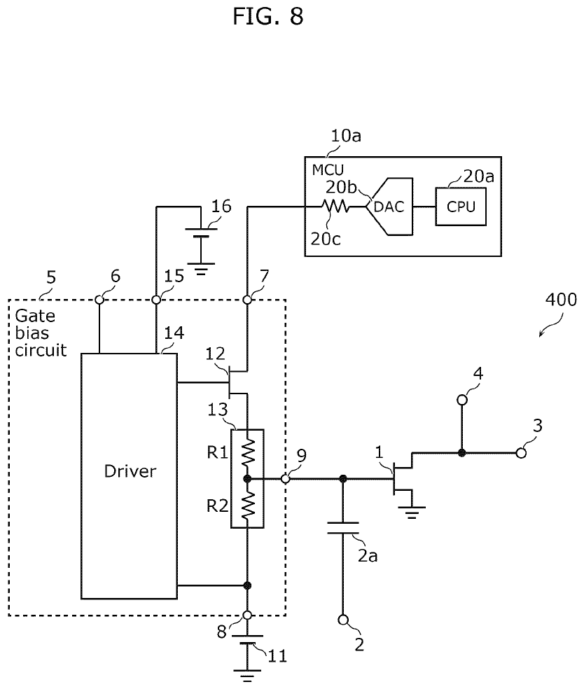

FIG. 8 is a diagram illustrating radio frequency power amplifier 400 according to Embodiment 4. Radio frequency power amplifier 400 is an example in which high voltage power supply for bias 10 of radio frequency power amplifier 100 according to Embodiment 1 is constituted by a micro controller unit (MCU) 10a. Hereafter, descriptions will be provided with a focus on the points different from radio frequency power amplifier 100 according to Embodiment 1.

According to the present embodiment, radio frequency power amplifier 400 includes MCU 10a as a high voltage power supply for bias. MCU 10a includes processor (CPU) 20a that outputs a digital value according to a built-in program, digital-to-analog converter (DAC) 20b that converts the digital value output by processor 20a into analog voltage, and fixed resistor 20c that acts as an output resistance for the analog voltage output by digital-to-analog converter 20b.

In general, the idle current of power amplification transistor 1 varies with respect to the operating temperature of power amplification transistor 1. When the idle current decreases, there is a possibility of a decrease in the gain of radio frequency power amplifier 400 and degradation of the distortion characteristics. On the other hand, when the idle current increases, there is a possibility of degradation in power efficiency of radio frequency power amplifier 400 and destruction of power amplification transistor 1.

In radio frequency power amplifier 400 according to Embodiment 4, high voltage power supply for bias 10 is constituted by MCU 10a, and changes an output voltage from MCU 10a with respect to the operating temperature of power amplification transistor 1, thereby keeping the idle current of power amplification transistor 1 constant. More specifically, when idle current of power amplification transistor 1 decreases due to a temperature change, processor 20a adjusts the output voltage from MCU 10a to be higher. On the other hand, when idle current of power amplification transistor 1 increases due to a temperature change, processor 20a adjusts the output voltage from MCU 10a to be lower. As to the output voltage from MCU 10a, an output voltage value with respect to the operating temperature of power amplification transistor 1 may be stored in advance in memory or the like in MCU 10a.

With radio frequency power amplifier 400 according to Embodiment 4, it is possible to keep the idle current constant with respect to the operating temperature of power amplification transistor 1.

It should be noted that radio frequency power amplifier 400 according to Embodiment 4 has been described with the example in which high voltage power supply for bias 10 of radio frequency power amplifier 100 according to Embodiment 1 is constituted by MCU 10a, but high voltage power supply for bias 10 of radio frequency power amplifier 200 according to Embodiment 2 and high voltage power supply for bias 10 of radio frequency power amplifier 300 according to Embodiment 3 may be constituted by MCU 10a.

As described above, radio frequency power amplifier 400 according to the present embodiment further includes, in addition to the structural components of radio frequency power amplifier 100 according to Embodiment 1, MCU 10a as high voltage power supply for bias 10. In radio frequency power amplifier 400, MCU 10a includes processor 20a that controls an output voltage of MCU 10a.

According to this configuration, for example, processor 20a adjusts the output voltage of MCU 10a to be increased when an idle current of power amplification transistor 1 decreases with respect to a temperature change, and adjusts the output voltage of MCU 10a to be decreased when the idle current of power amplification transistor 1 increases with respect to the temperature change. As a result, it is possible to keep the idle current constant with respect to the operating temperature of power amplification transistor 1.

### Embodiment 5

Next, a radio frequency power amplifier according to Embodiment 5 will be described.

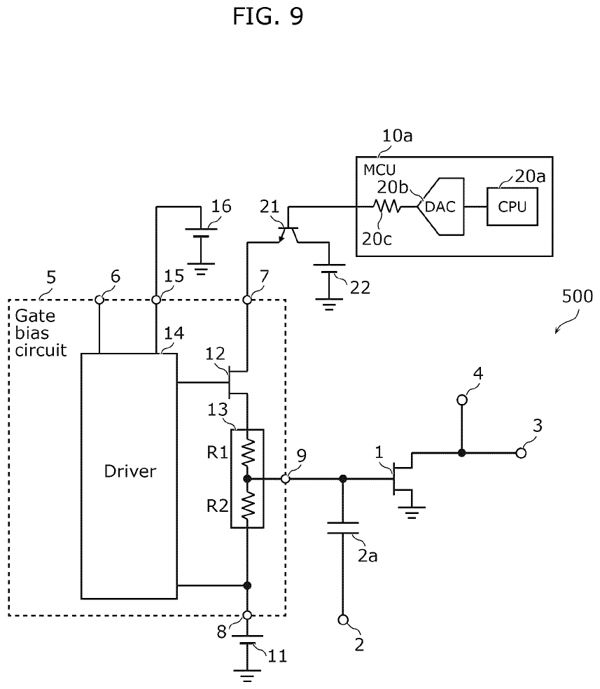

FIG. 9 is a diagram illustrating radio frequency power amplifier 500 according to Embodiment 5. Radio frequency power amplifier 500 has a configuration in which transistor for current amplification 21 with current amplification factor hfe is added between MCU 10a and VHb terminal 7 of radio frequency power amplifier 400 according to Embodiment 4. Hereafter, descriptions will be provided with a focus on the points different from radio frequency power amplifier 400 according to Embodiment 4.

Transistor for current amplification 21 includes a base connected to MCU 10a, a collector connected to power supply for current amplification 22, and an emitter connected to VHb terminal 7.

Currents flow through gate bias circuit 5 regardless of whether the enable signal is an ON signal or an OFF signal. The currents that flow through gate bias circuit 5 also flow through MCU 10a. Since radio frequency power amplifier 500 according to Embodiment 5 has a configuration in which transistor for current amplification 21 is added between MCU 10a and VHb terminal 7, the current flowing through MCU 10a can be 1/hfe of the current flowing through gate bias circuit 5. It should be noted that hfe is a current amplification factor of transistor for current amplification 21.

As described above, radio frequency power amplifier 500 according to the present embodiment further includes transistor for current amplification 21 connected between MCU 10a and VHb terminal 7, in addition to the structural components of radio frequency power amplifier 400 according to Embodiment 4. The base of transistor for current amplification 21 is connected to MCU 10a, the collector of transistor for current amplification 21 is connected to power supply for current amplification 22, and the emitter of transistor for current amplification 21 is connected to VHb terminal 7.

With radio frequency power amplifier 500 according to Embodiment 5, since transistor for current amplification 21 is provided, it is possible to decrease the current that flows through MCU 10a.

Although the radio frequency power amplifier according to the present disclosure has been described so far based on Embodiments 1 to 5, the present disclosure is not limited to Embodiments 1 to 5. Those skilled in the art will readily appreciate that various modifications may be made in Embodiments 1 to 5 and that other embodiments may be obtained by arbitrarily combining the structural components of these embodiments without materially departing from the novel teachings and advantages of the present disclosure. Accordingly, all such modifications and other embodiments are included in the present disclosure.

For example, radio frequency power amplifier 500 according to Embodiment 5 has been described with the example in which high voltage power supply for bias 10 of radio frequency power amplifier 100 according to Embodiment 1 is constituted by MCU 10a and transistor for current amplification 21, but high voltage power supply for bias 10 of radio frequency power amplifier 200 according to Embodiment 2 and high voltage power supply for bias 10 of radio frequency power amplifier 300 according to Embodiment 3 may be constituted by MCU 10a and transistor for current amplification 21.

In addition, although the invention according to the present disclosure has been a radio frequency power amplifier, it is not limited to this, and may be only the characteristic gate bias circuit 5 included by the radio frequency power amplifier, or a base station for radio communications including a radio frequency power amplifier according to the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The radio frequency power amplifier according to the present disclosure can reduce the rise time while keeping the standby current in the OFF state less than or equal to a certain value, and can be used as a radio frequency power amplifier for a base station for radio communications of a TDD system.

1. A radio frequency power amplifier comprising:
a power amplification transistor that includes a gate through which a radio frequency signal is input, a drain to output an amplified radio frequency signal, and a source connected to a ground potential; and
a gate bias circuit that supplies a gate bias voltage to the gate of the power amplification transistor, wherein
the gate bias circuit includes a first terminal connected to a high voltage power supply for bias, a second terminal connected to a low voltage power supply for bias, a third terminal that receives an enable signal, an enable transistor and a voltage dividing resistor that are connected in series and connected between the first terminal and the second terminal, a driver that outputs a voltage to a control terminal of the enable transistor, and a fourth terminal that outputs, as the gate bias voltage, a divided voltage generated by the voltage dividing resistor,
the enable signal indicates a first logic when the radio frequency signal is not input to the gate of the power amplification transistor, and indicates a second logic when the radio frequency signal is input to the gate of the power amplification transistor, and
the gate bias circuit:
when the enable signal received by the third terminal indicates the first logic, outputs, through the fourth terminal, a voltage to turn off an operation of the power amplification transistor as the gate bias voltage, as a result of the driver (i) supplying the control terminal of the enable transistor with a voltage higher than a lowest voltage among voltages supplied to the driver and (ii) causing the enable transistor to operate in a first operating area that is not a cutoff region; and
when the enable signal received by the third terminal indicates the second logic, outputs, through the fourth terminal, a voltage to turn on an operation of the power amplification transistor as the gate bias voltage, as a result of the driver causing the enable transistor to operate in a second operating area different from the first operating area.

2. The radio frequency power amplifier according to claim 1, wherein
the enable transistor is a field effect transistor, and the first operating area is a saturation region, or
the enable transistor is a bipolar transistor, and the first operating area is an active region.

3. The radio frequency power amplifier according to claim 2, wherein
a voltage that is denoted by Vgef, and is applied by the driver to the control terminal of the enable transistor to cause the enable transistor to operate in the first operating area satisfies
$$Vgef > Vte + [ ( Vtm - Z - VLb ) \times VHb + ( Y + Z ) \times VLb ] / ( Vtm + Y - VLb ) ,$$
where Vtm denotes a threshold voltage of the power amplification transistor, Vte denotes a threshold voltage of the enable transistor, VHb denotes a voltage supplied to the first terminal, VLb denotes a voltage supplied to the second terminal, Von denotes a gate bias voltage output by the gate bias circuit to turn on an operation of the power amplification transistor, Y denotes Von−Vtm that is a voltage difference between Von and Vtm, Voff denotes a gate bias voltage output by the gate bias circuit to turn off an operation of the power amplification transistor, and Z denotes Vtm−Voff that is a voltage difference between Vtm and Voff, Y is greater than zero, and Z is greater than zero.

4. The radio frequency power amplifier according to claim 2, further comprising:
a variable resistor connected between the voltage dividing resistor and the second terminal, wherein
the driver controls a resistance value of the variable resistor to satisfy Rvo<Rvf, where Rvf denotes the resistance value of the variable resistor when the enable signal indicating the first logic is received by the third terminal, and Rvo denotes the resistance value of the variable resistor when the enable signal indicating the second logic is received by the third terminal.

5. The radio frequency power amplifier according to claim 4, wherein
the variable resistor is a transistor, and the driver switches the resistance value of the variable resistor to Rvo or to Rvf, by applying a voltage generated using the enable signal received by the third terminal to a control terminal of the transistor.

6. The radio frequency power amplifier according to claim 4, wherein
$$Rvf = Rvo + 1 / Ibof \times [ ( Vtm - Z - VLb ) \times VHb - ( Vgef - Vte ) \times ( Vtm + Y - VLb ) + ( Y + Z ) \times VLb ] / [ VHb - ( Vtm + Y ) ] ,$$
where Ibof denotes a current flowing between the first terminal and the second terminal when the enable signal indicating the first logic is received by the third terminal, Vgef denotes a voltage that is applied by the driver to the control terminal of the enable transistor to cause the enable transistor to operate in the first operating area, Vtm denotes a threshold voltage of the power amplification transistor, Vte denotes a threshold voltage of the enable transistor, VHb denotes a voltage supplied to the first terminal, VLb denotes a voltage supplied to the second terminal, Y denotes Von−Vtm that is a voltage difference between Von and Vtm, Von denotes a gate bias voltage output by the gate bias circuit to turn on an operation of the power amplification transistor, Z denotes Vtm−Voff that is a voltage difference between Vtm and Voff, Voff denotes a gate bias voltage output by the gate bias circuit to turn off an operation of the power amplification transistor, Y is greater than zero, and Z is greater than zero.

7. The radio frequency power amplifier according to claim 4, wherein
when the enable signal changes from a signal indicating the first logic to a signal indicating the second logic, the driver causes the enable transistor to switch from operating in the first operating area to operating in the second operating area after switching the resistance value of the variable resistor from Rvf to Rvo.

8. The radio frequency power amplifier according to claim 4, further comprising:
a fixed resistor connected in parallel with the variable resistor.

9. The radio frequency power amplifier according to claim 2, further comprising:
the high voltage power supply for bias, wherein
the high voltage power supply for bias includes a processor that controls an output voltage of the high voltage power supply for bias.

10. The radio frequency power amplifier according to claim 9, wherein
the processor adjusts the output voltage of the high voltage power supply for bias to be increased when an idle current of the power amplification transistor decreases with respect to a temperature change, and adjusts the output voltage of the high voltage power supply for bias to be decreased when the idle current of the power amplification transistor increases with respect to the temperature change.

11. The radio frequency power amplifier according to claim 9, further comprising:
a transistor for current amplification connected between the processor and the first terminal, wherein
the transistor for current amplification includes a base connected to the processor, a collector connected to a power supply for current amplification, and an emitter connected to the first terminal.
